(19) United States
(12) Patent Application Publication
(10) Pub. No.: US 2015/0109045 A1
(43) Pub. Date: Apr. 23, 2015

(54) SCALABLE LAYOUT ARCHITECTURE FOR METAL-PROGRAMMABLE VOLTAGE LEVEL SHIFTER CELLS

(71) Applicant: QUALCOMM Incorporated, San Diego, CA (US)

(72) Inventors: Ramaprasath Vilangudipitchai, San Diego, CA (US); Ohsang Kwon, San Diego, CA (US); Srivatsan Thiruvengadam, Carlsbad, CA (US)

(73) Assignee: QUALCOMM Incorporated, San Diego, CA (US)

(21) Appl. No.: 14/059,361

(22) Filed: Oct. 21, 2013

(51) Int. Cl. H03K 19/0185

(52) U.S. Cl. CPC H03K 19/018585; H03K 19/018528
USPC 327/333

(57) ABSTRACT

A layout architecture for voltage level shifters is provided. The architecture includes features of voltage level shifter cells and arrangements of the voltage level shifter cells within integrated circuits. The architecture can be used, for example, in CMOS system-on-a-chip integrated circuits implemented using metal-programmable standard cells. The architecture is also scalable for interfaces having different numbers of signals. The architecture can provide reduced area and improved performance.

### BACKGROUND

1. Field

The present invention relates to a layout architecture for voltage level shifters and, more particularly, to a layout architecture for voltage level shifters that is scalable and uses metal-programmable cells.

2. Background

Integrated circuits have grown increasingly complex. An integrated circuit may include blocks of circuits that operate using different voltages. The voltages for each block may be chosen according to the needs of each individual block. The supply voltage level for a block may be dynamically adjusted, for example, according to the requirements and performance of that block. Additionally, the voltage supply for a given block may be powered down to save power when the block is not used. Circuits and signals that operate using a particular voltage supply can be referred to as being in a supply domain.

As integrated circuits have grown more complex. It has also become desirable to organize the physical arrangement of the circuits in a regular fashion. The increasing complexity also drives a desire to use common modules and cells in the various circuit blocks of an integrated circuit.

Some signals communicate between blocks that operate in different supply domains. Circuits that translate the voltage levels for these signals are referred to as voltage level shifters. The voltage level shifters that translate signals for supply domains internal to an integrated circuit may be referred to as core-to-core voltage level shifters. A voltage level shifter may, for example, translate a logic signal from a 0.8 V supply domain to a 1.2 V supply domain. Providing improved voltage level shifter cells can provide an improved integrated circuit. For example, voltage level shifter cells that occupy a small area and that can be flexibly located within the integrated circuit may improve the performance (e.g., by improved signal routing) and reduce the size of the integrated circuit.

### SUMMARY

A layout architecture for voltage level shifters is provided. The architecture includes features of voltage level shifter cells and arrangements of the voltage level shifter cells within integrated circuits. The architecture can be used, for example, in CMOS system-on-a-chip integrated circuits. The architecture is also scalable for interfaces with different numbers of signals. The architecture can provide reduced area and improved performance.

In one aspect, an integrated circuit is provided that includes: a standard cell box comprising rows of standard cells, a first row and a second row of the rows of standard cells including a first well region extending across the standard cell box, a third row and a fourth row of the rows of standard cells including a second well region extending across the standard cell box; a first voltage level shifter cell configured to translate a first input signal in a first supply domain to a first output signal in a second supply domain, the first voltage level shifter cell including a first circuit area including circuitry configured to receive the first input signal, the first circuit area including transistors formed in the first well region, and a second circuit area including circuitry configured to output the first output signal, the second circuit area including transistors formed in the second well region; and a second voltage level shifter cell configured to translate a second input signal in the second supply domain to a second output signal in the first supply domain, the second voltage level shifter cell including a first circuit area including circuitry configured to receive the second input signal, the first circuit area including transistors formed in the second well region, and a second circuit area including circuitry configured to output the second output signal, the second circuit area including transistors formed in the first well region.

In one aspect, an integrated circuit is provided that includes: a first standard cell box and a second standard cell box, each standard cell box comprising rows of standard cells, each of the rows of standard cells including a well region extending across the respective standard cell box; a column of well taps disposed between the first and the second standard cell boxes; a first voltage level shifter cell configured to translate a first input signal in a first supply domain to a first output signal in a second supply domain, the first voltage level shifter cell including a first circuit area including circuitry configured to receive the first input signal, the first circuit area disposed in a portion of a first one of the rows of standard cells of the first standard cell box, the first circuit area including transistors formed in the well region of the first one of the rows of standard cells of the first standard cell box, and a second circuit area including circuitry configured to output the first output signal, the second circuit area disposed in a portion of a first one of the rows of standard cells of the second standard cell box, the second circuit area including transistors formed in the well region of the first one of the rows of standard cells of the second standard cell box; and a second voltage level shifter cell configured to translate a second input signal in the second supply domain to a second output signal in the first supply domain, the second voltage level shifter cell including a first circuit area including circuitry configured to receive the second input signal, the first circuit area disposed in a portion of a second one of the rows of standard cells of the second standard cell box, the first circuit area including transistors formed in the well region of the second one of the rows of standard cells of the second standard cell box, and a second circuit area including circuitry configured to output the second output signal, the second circuit area disposed in a portion of a second one of the rows of standard cells of the first standard cell box, the second circuit area including transistors formed in the well region of the second one of the rows of standard cells of the first standard cell box.

In one aspect, an integrated circuit is provided that includes: a standard cell box comprising rows of standard cells, a first row and a second row of the rows of standard cells including a first well region extending across the standard cell box, a third row and a fourth row of the rows of standard cells including a second well region extending across the standard cell box; a means for translating a first input signal in a first supply domain to a first output signal in a second supply domain, the means for translating including a first circuit area including circuitry configured to receive the first input signal, the first circuit area including transistors formed in the first well region, and a second circuit area including circuitry configured to output the first output signal, the second circuit area including transistors formed in the second well region; and a means for translating a second input signal in the second supply domain to a second output signal in the first supply domain, the means for translating including a first circuit area including circuitry configured to receive the second input signal, the first circuit area including transistors formed in the second well region, and a second circuit area including circuitry configured to output the second output signal, the second circuit area including transistors formed in the first well region.

In one aspect, an integrated circuit is provided that includes: a first standard cell box and a second standard cell box, each standard cell box comprising rows of standard cells, each of the rows of standard cells including a well region extending across the respective standard cell box; a column of well taps disposed between the first and the second standard cell boxes; a means for translating a first input signal in a first supply domain to a first output signal in a second supply domain, the means for translating including a first circuit area including circuitry configured to receive the first input signal, the first circuit area disposed in a portion of a first one of the rows of standard cells of the first standard cell box, the first circuit area including transistors formed in the well region of the first one of the rows of standard cells of the first standard cell box, and a second circuit area including circuitry configured to output the first output signal, the second circuit area disposed in a portion of a first one of the rows of standard cells of the second standard cell box, the second circuit area including transistors formed in the well region of the first one of the rows of standard cells of the second standard cell box; and a means for translating a second input signal in the second supply domain to a second output signal in the first supply domain, the means for translating including a first circuit area including circuitry configured to receive the second input signal, the first circuit area disposed in a portion of a second one of the rows of standard cells of the second standard cell box, the first circuit area including transistors formed in the well region of the second one of the rows of standard cells of the second standard cell box, and a second circuit area including circuitry configured to output the second output signal, the second circuit area disposed in a portion of a second one of the rows of standard cells of the first standard cell box, the second circuit area including transistors formed in the well region of the second one of the rows of standard cells of the first standard cell box.

In one aspect, a circuit operation method is provided that includes: providing a standard cell box comprising rows of standard cells, a first row and a second row of the rows of standard cells including a first well region extending across the standard cell box, a third row and a fourth row of the rows of standard cells including a second well region extending across the standard cell box; translating a first input signal in a first supply domain to a first output signal in a second supply domain using a first voltage level shifter cell comprising: a first circuit area including circuitry configured to receive the first input signal, the first circuit area including transistors formed in the first well region, and a second circuit area including circuitry configured to output the first output signal, the second circuit area including transistors formed in the second well region; and translating a second input signal in the second supply domain to a second output signal in the first supply domain using a second voltage level shifter cell comprising: a first circuit area including circuitry configured to receive the second input signal, the first circuit area including transistors formed in the second well region, and a second circuit area including circuitry configured to output the second output signal, the second circuit area including transistors formed in the first well region.

Other features and advantages of the present invention should be apparent from the following description which illustrates, by way of example, aspects of the invention.

### BRIEF DESCRIPTION OF THE DRAWINGS

The details of the present invention, both as to its structure and operation, may be gleaned in part by study of the accompanying drawings, in which like reference numerals refer to like parts, and in which:

FIG. 1 is a block diagram of a layout of an integrated circuit according to a presently disclosed embodiment;

FIG. 2 is a block diagram of a layout of a block of the integrated circuit of FIG. 1;

FIG. 3 is a block diagram of a layout of a standard cell box according to a presently disclosed embodiment;

FIG. 4 is a layout view of a portion of the standard cell box of FIG. 3;

FIG. 5 is a block diagram of another layout of standard cell boxes according to a presently disclosed embodiment;

FIG. 6 is a layout view of a portion of the standard cell boxes of FIG. 5; and

FIG. 7 is schematic diagram of a voltage level shifter circuit according to a presently disclosed embodiment.

### DETAILED DESCRIPTION

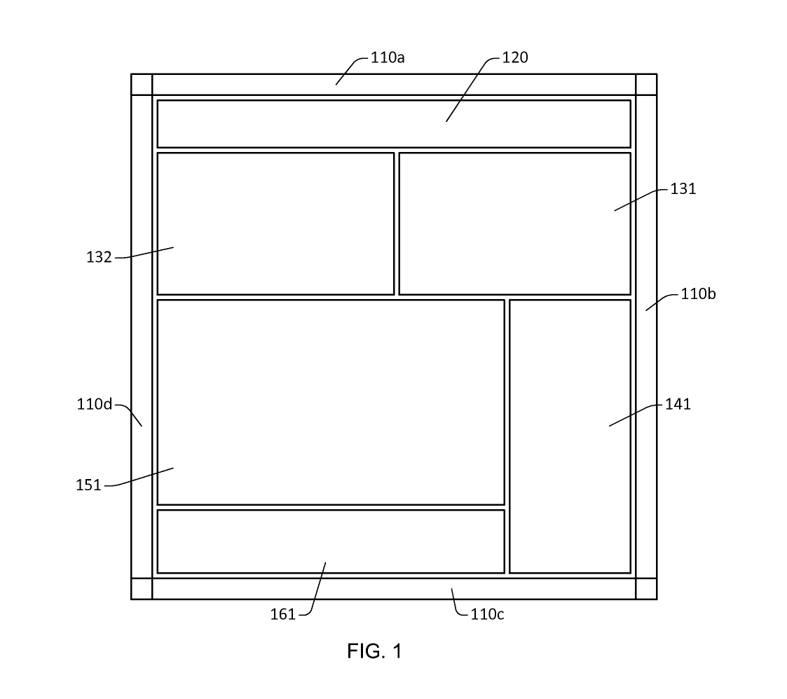

FIG. 1 is a block diagram of a layout of an integrated circuit according to a presently disclosed embodiment. Example integrated circuits and voltage level shifters will be described for n-well CMOS technology. However, the circuits and their layouts described herein can be adapted to other technologies, for example, p-well and twin-well CMOS technologies.

The integrated circuit layout includes four periphery blocks 110 (110a, 110b, 110c, and 110d) located on the edges of the integrated circuit. The periphery blocks 110 include circuits to interface to devices outside the integrated circuit. Other blocks in the example integrated circuit include an analog front end block 120, a modem block 132, a graphics processor block 131, a microprocessor block 151, a memory block 141, and an interface block 161.

The various blocks of the integrated circuit may operate in different supply domains. For example, the graphics processor block 131 may operate in a 1.2 volt (V) domain and the microprocessor block 151 may operate in a 0.8 V domain. Signals that communicate between the graphics processor block 131 and the microprocessor block 151 are level shifted, for example, using voltage level shifters, when they pass between the blocks. There may be a large number of signals that communicate in each direction.

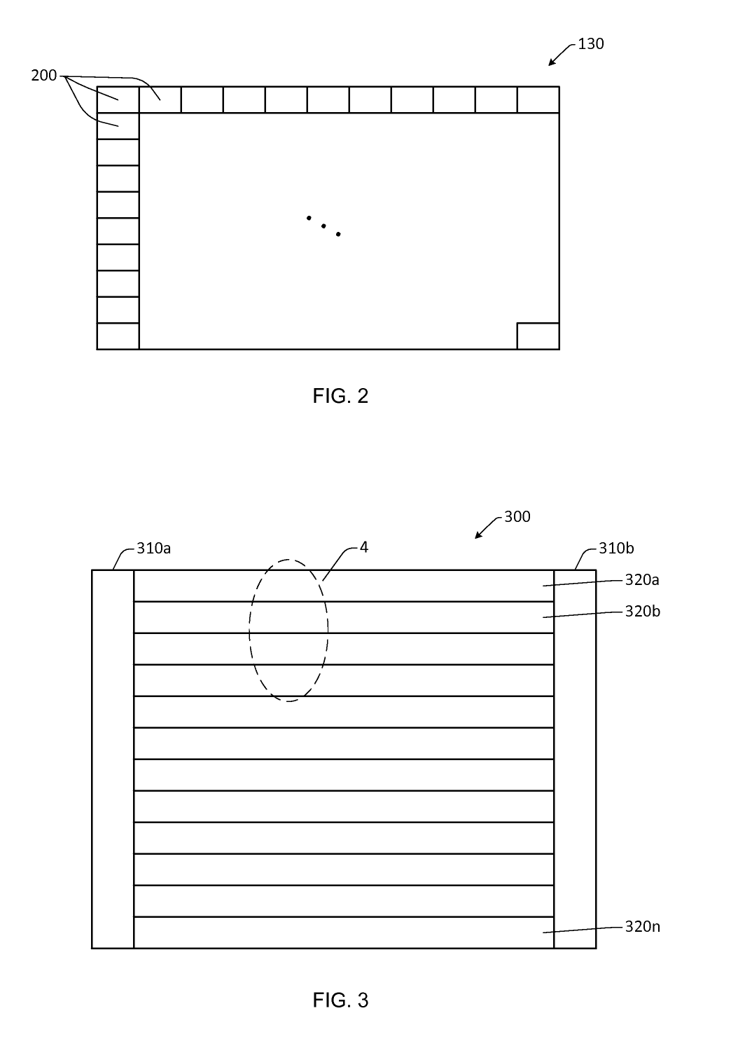

FIG. 2 is a block diagram of a layout of a block 130 of the integrated circuit of FIG. 1. The block 130 may be, for example, the modem block 132, the graphics processor block 131, or the microprocessor block 151. The block 130 illustrated in FIG. 2 is rectangular. Other rectilinear shapes may also be used.

The block 130 includes an array of standard cell boxes (or sub blocks) 200. Each of the standard cell boxes 200 includes rows of logic cells. The logic cells, in an embodiment, are metal-programmable standard cells. The metal-programmable standard cells include common base layers that are programmed by metal layers. For example, the circuit layers from the gate layer downward may be common to all of the standard cells in a standard cell box.

The standard cell boxes may be the same or may be different between blocks. For example, the standard cell boxes in one block may be twice the width of the standard cell boxes in another one of the blocks. The standard cell boxes, in an embodiment, have the same orientation with the transistors in all the boxes being parallel.

FIG. 3 is a block diagram of a layout of a standard cell box 300 according to a presently disclosed embodiment. The standard cell box 300 may be used to implement one of the standard cell boxes 200 of the block illustrated in FIG. 2. The standard cell box 300 includes rows 320 (320a, 320b, . . . , 320n) of metal-programmable standard cells. Each of the rows 320 includes the same layout for the base layers. However, the orientations of the base layers may vary, for example, by rotation or mirroring, between rows. The functions of the cells are programmed by varying the metal layers used to interconnect the base layers in each of the cells.

The standard cell box 300 includes well tap blocks 310 (310a and 310b) on opposite edges of the standard cell box. A well tap block may be referred to as a column of well taps based on the general orientation of the well tap block being perpendicular to the standard cell rows. The well tap blocks 310 include columns of connections to the wells that are used in the standard cell rows. For each row, the well tap blocks 310 can include a tap to the n-well and to the p-substrate. The tap to the p-substrate in the example standard cell box 300 is to a common VSS signal. The tap to the n-well in the example standard cell box 300 may be to a different voltage supply depending on the circuits in the associated row. One of the well tap blocks 310 may provide well taps for two adjacent standard cell boxes. The spacing of the well taps (and the width of the standard cell rows) can be determined based on a spacing that prevents latchup in the process technology used to implement the integrated circuit.

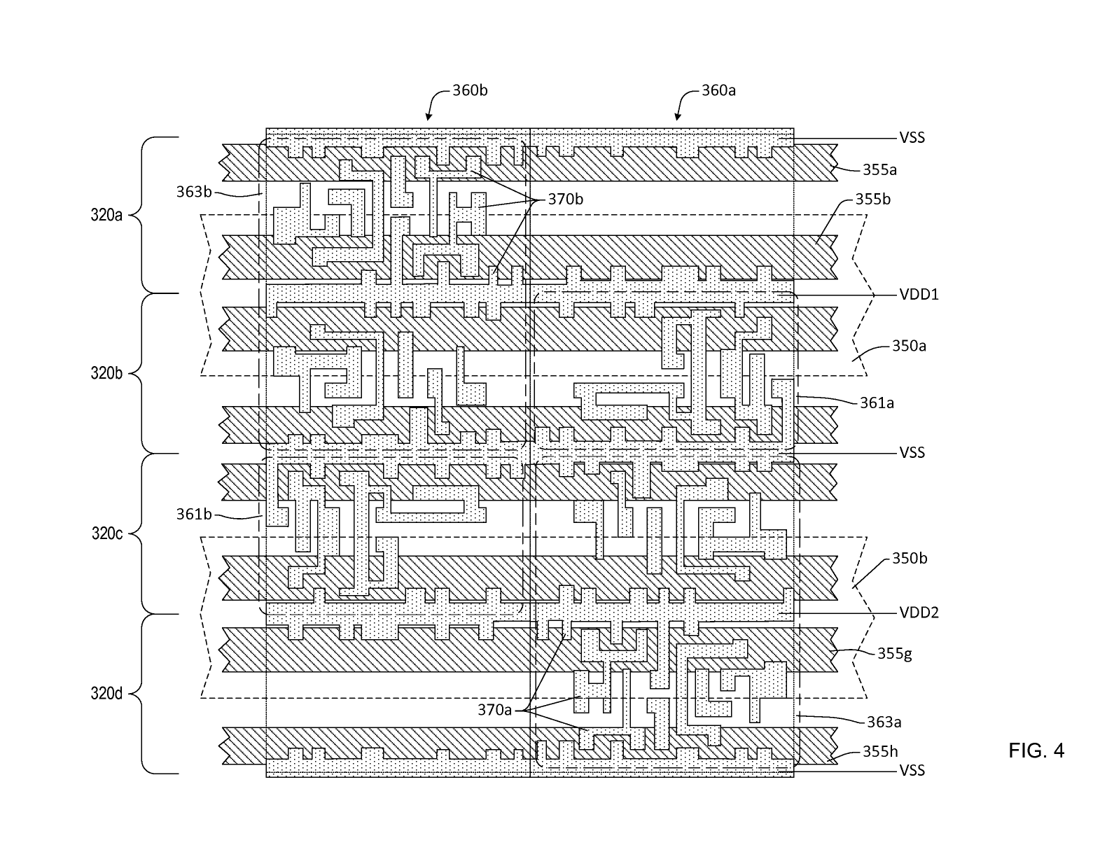

FIG. 4 is a layout view of a portion 4 of the standard cell box of FIG. 3. In the interest of clarity, FIG. 4 shows portions of only three integrated circuit layers—an n-well layer, a diffusion layer, and a first metal layer. An implementation of the standard cell box 300 includes many additional layers.

The standard cell box 300 includes a first voltage level shifter cell 360a and a second voltage level shifter cell 360b. The first voltage level shifter cell 360a translates a signal from a first supply domain to a second supply domain. The second voltage level shifter cell 360b translates a signal from the second supply domain to the first supply domain. Although FIG. 4 illustrates two voltage level shifter cells, other numbers of voltage level shifter cells may be placed in the standard cell box 300. Additionally, the voltage level shifter cells may be separated by other cells and may be placed in different rows.

Each of the voltage level shifter cells 360 uses parts of four standard cell rows 320. Alternate rows of standard cells in the standard cell box 300 have well regions in locations that are mirrored about the row axis. In the illustrated embodiment, the well regions are rectangular, thus the mirroring of the well locations from row to row may also be viewed as a 180° rotation. The locations of the well regions allow well regions to be combined between adjacent rows. A well region that is shared by two standard cell rows may be referred to as two well regions, although the two well regions are contiguous.

The mirroring of the rows of standard cells facilitates the layout of the second voltage level shifter cell 360b to be a 180° rotated (or mirrored) version of the layout of the first voltage level shifter cell 360a. The layout arrangement of the voltage level shifter cells 360 also allows the voltage level shifter cells to be adjacent. There is no additional spacing of the voltage level shifter cells or additional spacing within one of the voltage level shifter cells.

The well regions in the voltage level shifter cells 360 are connected to their respective voltage supplies within the well tap blocks 310. This layout arrangement allows well ties to be omitted from within the voltage level shifter cells 360. The well tap blocks 310 are present independent of whether the adjacent standard cell boxes include voltage level shifter cells.

The first row 320a of standard cells in the voltage level shifter cells 360 includes a first diffusion region 355a and a second diffusion region 355b. The diffusion regions, in the illustrated embodiment, are rectangular and extend across the standard cell rows 320. The diffusion regions are crossed by many gate regions (e.g., polysilicon) to form transistors. The first diffusion region 355a is n-type and is used to form n-channel transistors. The second diffusion region 355b is p-type and is used to form p-type transistors. The second diffusion region 355b is in the first n-well region 350a. The first n-well region 350a is coupled to a voltage supply VDD1 in the first supply domain. Various points of the diffusion regions and gates are interconnected according to the functions to be provided.

The fourth row 320d of standard cells in the voltage level shifter cells 360 includes an seventh diffusion region 355g and an eighth diffusion region 355h. The eighth diffusion region 355h is n-type, and the seventh diffusion region 355g is p-type. The seventh diffusion region 355g is in a second n-well region 350b. The second n-well region 350b is coupled to a voltage supply VDD2 in the second supply domain.

The first voltage level shifter cell 360a includes a first circuit area 361a located in the second standard cell row. The first circuit area 361a includes an input section of circuitry. The first circuit area 361a of the first voltage level shifter cell 360a may alternatively be located in the first standard cell row or the first standard cell row and the second standard cell row. The first voltage level shifter cell 360a includes a second circuit area 363a located in the third and fourth standard cell rows. The second circuit area 363a includes an output section of circuitry. The input section of circuitry includes circuitry that receives the input signal that will be level shifted, and the output section of circuitry includes circuitry that outputs the level-shifted output signal.

The second voltage level shifter cell 360b includes a first circuit area 361b located in the third standard cell row. The first circuit area includes an input section of circuitry. The first circuit area 361b of the second voltage level shifter cell 360b may alternatively be located in the fourth standard cell row or the third standard cell row and the fourth standard cell row. The second voltage level shifter cell 360b includes a second circuit area 363b located in the first and second standard cell rows. The second circuit area 363b includes an output section of circuitry. The input section of circuitry includes circuitry that receives the input signal that will be level shifted, and the output section of circuitry includes circuitry that outputs the level-shifted output signal.

The second voltage level shifter cell 360b includes regions of the first metal layer 370b that are rotated versions of corresponding regions of the first metal layer 370a in the first voltage level shifter cell 360a. In the embodiment illustrated in FIG. 4, the rotation is about the midpoint of the right edge of the first voltage level shifter cell 360a. In an alternative embodiment, the layout of the second voltage level shifter cell 360b is mirrored about an axis parallel to the standard cell rows with respect to the layout of the first voltage level shifter cell 360a.

The arrangement of voltage level shifter cells is scalable for interfaces having different numbers of signals. Additionally, the voltage level shifter cells can be placed flexibly, for example, as appropriate for routing of the signals involved.

The arrangement of voltage level shifter cells illustrated in FIG. 4 may be used, for example, to provide voltage level shifters between a first circuit block that operates in the first supply domain that is located above (in the orientation of FIG. 4) the voltage level shifter cells and a second circuit block that operates in the second supply domain that is located below the voltage level shifter cells. This may provide good signal routing since the input and output sections of the voltage level shifters are located towards the corresponding circuit blocks.

The voltage level shifter cells for translating signals from the first supply domain to the second supply domain or for translating signals from the second supply domain to the first supply domain can be placed adjacent to each other and can be interspersed with other types of cells. This allows additional flexibility in placement of the voltage level shifter cells. The voltage level shifter cells can be placed, for example, as appropriate for routing of the signals involved.

The presently disclosed voltage level shifter cells can occupy smaller areas of the integrated circuit than prior voltage level shifter cells. Some prior voltage level shifter cells have required additional well-to-well spacing, for example, to avoid latchup, which can increase the size of the cells. Some prior voltage level shifter cells have required well taps within the cells, which can increase the size of the cells. The smaller area of the presently disclosed voltage level shifter cells can improve performance of an individual voltage level shifter cell, for example, by reducing variation in the transistors in the voltage level shifter circuit.

Although the embodiment of FIG. 4 uses four rows of standard cells, the number of rows could vary. Additionally, other circuits may be built in the areas (e.g., the first standard cell row of the first voltage level shifter cell 360a and the fourth standard cell row of the second voltage level shifter cell 360b) that do not include voltage level shifter circuitry.

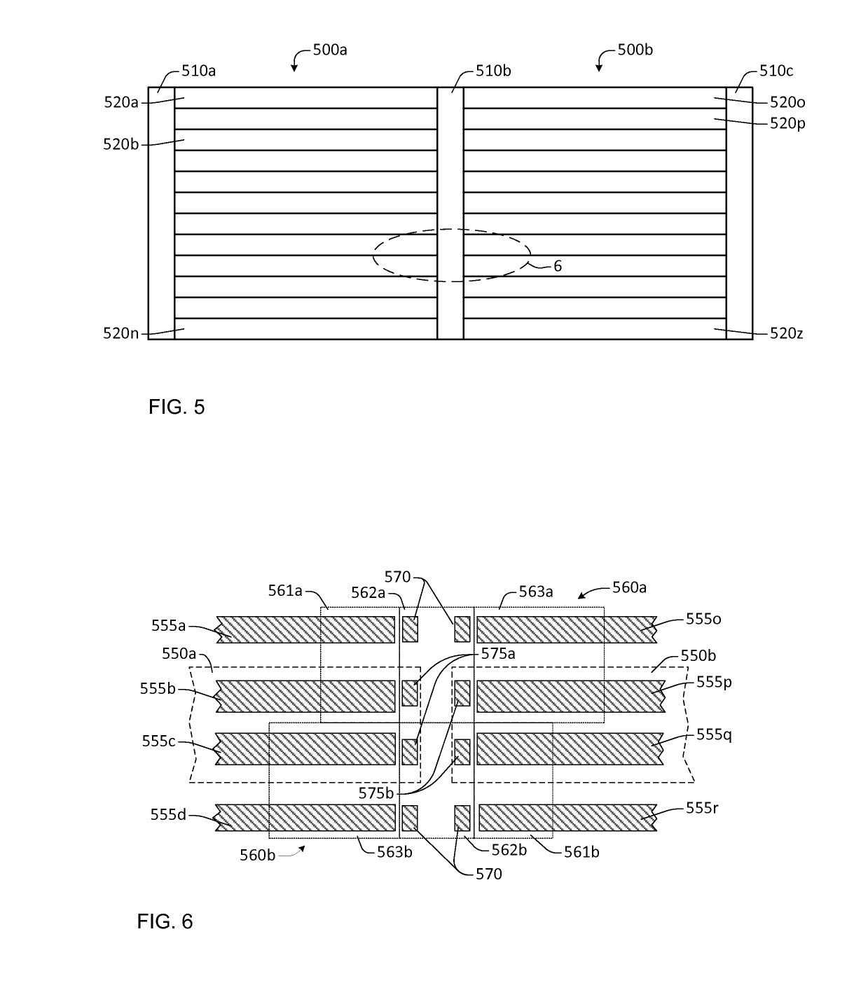

FIG. 5 is a block diagram of another layout of standard cell boxes according to a presently disclosed embodiment. The standard cell boxes 500 (500a and 500b) may be used, for example, to implement two of the standard cell boxes 200 illustrated in FIG. 2. The standard cell boxes 500 include rows of metal-programmable standard cells 520 (520a, 520b, . . . , 520z). Each of the rows includes the same layout for the base layers. However, the orientations of the base layers may vary between rows. The functions of the cells are programmed by varying the metal layers used to interconnect the base layers in each of the cells.

The standard cell boxes 500 include well tap blocks 510 (510a, 510b, and 510c) on edges of the standard cell boxes. The well tap blocks 510 include connections to the well regions that are used in the standard cell rows. For each row, the well tap blocks 510 can include a tap to the n-well and a tap to the p-substrate. The tap to the p-substrate in the example standard cell boxes 500 is to a common VSS signal. The tap to the n-well in the example standard cell boxes 500 may be to a different voltage supply depending on the circuits in the associated row. Additionally, the taps to the n-wells for a standard cell row in the first standard cell box 500a may be different than the taps to the n-wells for the corresponding standard cell rows in the second standard cell box 500b.

FIG. 6 is a layout view of a portion 6 of the standard cell boxes of FIG. 5. In the interest of clarity, FIG. 6 shows portions of only two integrated circuit layers—an n-well layer and a diffusion layer. An implementation of the standard cell boxes 500 includes many additional layers.

The standard cell boxes 500 includes a first voltage level shifter cell 560a and a second voltage level shifter cell 560b. The first voltage level shifter cell 560a translates a signal from a first supply domain to a second supply domain. The second voltage level shifter cell 560b translates a signal from the second supply domain to the first supply domain. Although FIG. 6 illustrates two voltage level shifter cells, a greater number of voltage level shifter cells may be placed in the standard cell boxes 500.

Each of the voltage level shifter cells uses part of a standard cell row in the first standard cell box 500a and part of a standard cell row in the second standard cell box 500b. Alternate rows of standard cells in the standard cell boxes 500 have well regions in locations that are mirrored about the row axis so that well regions can be combined between adjacent rows. This allows the layout of the second voltage level shifter cell 560b to be a rotated version of the layout of the first voltage level shifter cell 560a and the two voltage level shifter cells to be adjacent.

The portion of the voltage level shifter cells 560 in the first standard cell box 500a includes a first diffusion region 555a, a second diffusion region 555b, a third diffusion region 555c, and a fourth diffusion region 555d. The first diffusion region 555a and the fourth diffusion region 555d are n-type and are used to form n-channel transistors. The second diffusion region 555b and the third diffusion region 555c are p-type and are used to form p-type transistors. The second diffusion region 555b and the third diffusion region 555c are in a first n-well region 550a. The first n-well region 550a is coupled to a voltage supply in the first supply domain.

The portion of the voltage level shifter cells 560 in the second standard cell box 500b includes a fifth diffusion region 555o, a sixth diffusion region 555p, a seventh diffusion region 555q, and an eighth diffusion region 555r. The fifth diffusion region 555o and the eighth diffusion region 555r are n-type. The sixth diffusion region 555p and the seventh diffusion region 555q are p-type. The sixth diffusion region 555p and the seventh diffusion region 555q are in a second n-well region 550b. The second n-well region 550b is coupled to a voltage supply in the second supply domain.

The first voltage level shifter cell 560a includes a first circuit area 561a located in the first standard cell box 500a. The first circuit area includes an input section of circuitry. The first voltage level shifter cell 560a includes a second circuit area 563a located in the second standard cell box 500b. The second circuit area includes an output section of circuitry. The first voltage level shifter cell 560a also includes a well tap area 562a located in the well tap block 510b between the first standard cell box 500a and the second standard cell box 500b. The input section of circuitry includes circuitry that receives the input signal that will be level shifted, and the output section of circuitry includes circuitry that outputs the level-shifted output signal.

The second voltage level shifter cell 560b includes a first circuit area 561b located in the second standard cell box 500b. The first circuit area includes an input section of circuitry. The second voltage level shifter cell 560b includes a second circuit area 563b located in the first standard cell box 500a. The second circuit area includes an output section of circuitry. The second voltage level shifter cell 560b also includes a well tap area 562b located in the well tap block 510b between the first standard cell box 560a and the second standard cell box 560b. The input section of circuitry includes circuitry that receives the input signal that will be level shifted, and the output section of circuitry includes circuitry that outputs the level-shifted output signal.

The well tap block 510 in the area of the voltage level shifter cells includes first well taps 575a. The first well taps 575a use n-type diffusion regions to connect the first n-well region 550a to the voltage supply in the first supply domain. The well tap block 510 in the area of the voltage level shifter cells also includes second well taps 575b. The second well taps 575b use n-type diffusion regions to connect the second n-well region 550b to the voltage supply in the second supply domain. The well tap block 510 in the area of the voltage level shifter cells also includes p-substrate taps 570 to connect to the p-substrate near the voltage level shifter cells.

The well taps are also used at standard cell rows 520 that do not have voltage level shifter cells. Thus, the voltage level shifter cells can be located without the use of special-purpose well taps that could be difficult to place and could increase the area of the voltage level shifter cells.

The arrangement of voltage level shifter cells illustrated in FIG. 6 may be used, for example, to provide voltage level shifters between a circuit block that operates in the first supply domain that is located to the left of the voltage level shifter cells and a circuit block that operates in the second supply domain that is located to the right of the voltage level shifter cells. The voltage level shifter cells for translating signals from the first supply domain to the second supply domain or for translating signals from the second supply domain to the first supply domain can be placed adjacent to each other and can be interspersed with other types of cells. This allows the voltage level shifter cells to be placed flexibly as appropriate for routing of the signals involved.

A multi-bit voltage level shifter cell may be formed in a similar manner. For example, a two-bit voltage level shifter cell may be formed with an input section of circuitry for two level shifters located in one standard cell box and an output section of circuitry for the two level shifters located in the next standard cell box.

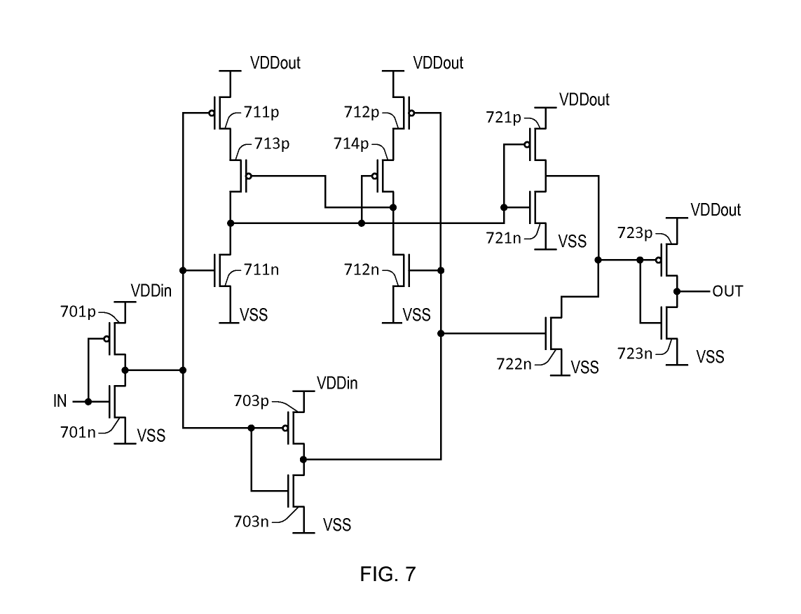

FIG. 7 is schematic diagram of a voltage level shifter circuit according to a presently disclosed embodiment. The circuit may be used in the voltage level shifter cells described above. The voltage level shifter circuit receives an input signal IN and produces an output signal OUT. The input signal IN operates in a first supply domain that uses a first voltage supply VDDin and a ground reference VSS. The output signal OUT operates in a second supply domain that uses a second voltage supply VDDout and the ground reference VSS.

The input signal IN is inverted by a first input invertor formed by transistor 701p and transistor 701n. The output of the first input invertor is inverted by a second input invertor formed by transistor 703p and transistor 703n. The first input invertor and the second input invertor operate in the first supply domain.

The output of the first input invertor and the output of the second input invertor are amplified by the differential amplifier formed by transistor 711p, transistor 713p, transistor 711n, transistor 712p, transistor 714p, and transistor 712n. The differential amplifier operates in the second supply domain.

A first output invertor formed by transistor 721p and transistor 721n inverts the output of the differential amplifier. The output of the first output invertor is also switched to ground based on the output of the second input invertor by transistor 722n. The output of the first output invertor is inverted by a final output invertor formed by transistor 723p and transistor 723n to produce the output signal OUT. The first output invertor and the final output invertor operate in the second supply domain.

The voltage level shifter circuit may include variations, for example, voltage level shifter circuits that clamp the output signal to a particular logic value when the power supply domain used by the input signal to the voltage level shifter is powered down. The circuit variations may be built using metal-programmable standard cells that have a common layout size.

Although embodiments of the invention are described above for particular embodiments, many variations of the invention are possible including, for example, those with different aspect ratios and those in different process technologies. Directional terms, such above, above, below, left, and right, are used to describe some features. This terminology is used to provide clear and concise descriptions. The terms are relative and no particular absolute orientation should be inferred. Additionally, features of the various embodiments may be combined in combinations that differ from those described above.

Those of skill will appreciate that the various illustrative blocks and modules described in connection with the embodiments disclosed herein can be implemented in various forms. Some blocks and modules have been described above generally in terms of their functionality. How such functionality is implemented depends upon the design constraints imposed on an overall system. Skilled persons can implement the described functionality in varying ways for each particular application, but such implementation decisions should not be interpreted as causing a departure from the scope of the invention. In addition, the grouping of functions within a module, block, or step is for ease of description. Specific functions or steps can be moved from one module or block without departing from the invention.

Circuits implementing the embodiments and functional blocks and modules described herein can be realized using various transistor types, logic families, and design methodologies.

The above description of the disclosed embodiments is provided to enable any person skilled in the art to make or use the invention. Various modifications to these embodiments will be readily apparent to those skilled in the art, and the generic principles described herein can be applied to other embodiments without departing from the spirit or scope of the invention. Thus, it is to be understood that the description and drawings presented herein represent presently preferred embodiments of the invention and are therefore representative of the subject matter which is broadly contemplated by the present invention. It is further understood that the scope of the present invention fully encompasses other embodiments that may become obvious to those skilled in the art and that the scope of the present invention is accordingly limited by nothing other than the appended claims.

What is claimed is:

1. An integrated circuit, comprising:
a standard cell box comprising rows of standard cells, a first row and a second row of the rows of standard cells including a first well region extending across the standard cell box, a third row and a fourth row of the rows of standard cells including a second well region extending across the standard cell box;
a first voltage level shifter cell configured to translate a first input signal in a first supply domain to a first output signal in a second supply domain, the first voltage level shifter cell including:
a first circuit area including circuitry configured to receive the first input signal, the first circuit area including transistors formed in the first well region, and
a second circuit area including circuitry configured to output the first output signal, the second circuit area including transistors formed in the second well region; and
a second voltage level shifter cell configured to translate a second input signal in the second supply domain to a second output signal in the first supply domain,
the second voltage level shifter cell including:
a first circuit area including circuitry configured to receive the second input signal, the first circuit area including transistors formed in the second well region, and
a second circuit area including circuitry configured to output the second output signal, the second circuit area including transistors formed in the first well region.

2. The integrated circuit of claim 1, further comprising a column of well taps disposed adjacent an edge of the standard cell box, the column of well taps configured to connect the first well region to a voltage supply in the first supply domain and to connect the second well region to a voltage supply in the second supply domain.

3. The integrated circuit of claim 1, wherein the second voltage level shifter cell is substantially a copy of the first voltage level shifter cell mirrored about an axis parallel to the rows of standard cells.

4. The integrated circuit of claim 1, wherein the second voltage level shifter cell is substantially a copy of the first voltage level shifter cell rotated about a midpoint of an edge of the first voltage level shifter cell.

5. The integrated circuit of claim 1, wherein the rows of standard cells include metal-programmable standard cells.

6. The integrated circuit of claim 1, wherein the first input signal is routed to the first voltage level shifter cell from a first circuit block in the direction of the first row of standard cells from the fourth row of standard cells, and wherein the second input signal is routed to the second voltage level shifter cell from a second circuit block in the direction of the fourth row of standard cells from the first row of standard cells.

7. The integrated circuit of claim 1, wherein the first voltage level shifter cell is adjacent to the second voltage level shifter cell.

8. The integrated circuit of claim 1, wherein the first row of the rows of standard cells as adjacent an edge of the standard cell box.

9. An integrated circuit, comprising:
a first standard cell box and a second standard cell box, each standard cell box comprising rows of standard cells, each of the rows of standard cells including a well region extending across the respective standard cell box;
a column of well taps disposed between the first and the second standard cell boxes;
a first voltage level shifter cell configured to translate a first input signal in a first supply domain to a first output signal in a second supply domain, the first voltage level shifter cell including:
a first circuit area including circuitry configured to receive the first input signal, the first circuit area disposed in a portion of a first one of the rows of standard cells of the first standard cell box, the first circuit area including transistors formed in the well region of the first one of the rows of standard cells of the first standard cell box, and
a second circuit area including circuitry configured to output the first output signal, the second circuit area disposed in a portion of a first one of the rows of standard cells of the second standard cell box, the second circuit area including transistors formed in the well region of the first one of the rows of standard cells of the second standard cell box; and
a second voltage level shifter cell configured to translate a second input signal in the second supply domain to a second output signal in the first supply domain, the second voltage level shifter cell including:
a first circuit area including circuitry configured to receive the second input signal, the first circuit area disposed in a portion of a second one of the rows of standard cells of the second standard cell box, the first circuit area including transistors formed in the well region of the second one of the rows of standard cells of the second standard cell box, and
a second circuit area including circuitry configured to output the second output signal, the second circuit area disposed in a portion of a second one of the rows of standard cells of the first standard cell box, the second circuit area including transistors formed in the well region of the second one of the rows of standard cells of the first standard cell box.

10. The integrated circuit of claim 9, wherein the first one of the rows of standard cells of the first standard cell box and the first one of the rows of standard cells of the second standard cell box are collinear, and the second one of the rows of standard cells of the first standard cell box and the second one of the rows of standard cells of the second standard cell box are collinear.

11. The integrated circuit of claim 10, wherein the first circuit area of the first voltage level shifter cell is adjacent to the column of well taps, the second circuit area of the first voltage level shifter cell is adjacent to the column of well taps, the first circuit area of the second voltage level shifter cell is adjacent to the column of well taps, and the second circuit area of the second voltage level shifter cell is adjacent to the column of well taps.

12. The integrated circuit of claim 10, wherein the first one of the rows of standard cells of the first standard cell box and the second one of the rows of standard cells of the first standard cell box are adjacent.

13. The integrated circuit of claim 9, wherein the column of well taps:
provides a connection between the well region of the first one of the rows of standard cells of the first standard cell box and a voltage supply in the first supply domain,
provides a connection between the well region of the first one of the rows of standard cells of the second standard cell box and a voltage supply in the second supply domain,
provides a connection between the well region of the second one of the rows of standard cells of the first standard cell box and the voltage supply in the first supply domain, and
provides a connection between the well region of the second one of the rows of standard cells of the second standard cell box and the voltage supply in the second supply domain.

14. The integrated circuit of claim 13, wherein the well region of the first one of the rows of standard cells of the first standard cell box and the well region of the second one of the rows of standard cells of the first standard cell box are contiguous, and the well region of the first one of the rows of standard cells of the second standard cell box and the well region of the second one of the rows of standard cells of the second standard cell box are contiguous.

15. The integrated circuit of claim 9, wherein the second voltage level shifter cell is substantially a rotated copy of the first voltage level shifter cell.

16. The integrated circuit of claim 9, wherein the rows of standard cells include metal-programmable standard cells.

17. An integrated circuit, comprising:
a standard cell box comprising rows of standard cells, a first row and a second row of the rows of standard cells including a first well region extending across the standard cell box, a third row and a fourth row of the rows of standard cells including a second well region extending across the standard cell box;
a means for translating a first input signal in a first supply domain to a first output signal in a second supply domain,
the means for translating including
a first circuit area including circuitry configured to receive the first input signal, the first circuit area including transistors formed in the first well region, and
a second circuit area including circuitry configured to output the first output signal, the second circuit area including transistors formed in the second well region; and
a means for translating a second input signal in the second supply domain to a second output signal in the first supply domain,
the means for translating including
a first circuit area including circuitry configured to receive the second input signal, the first circuit area including transistors formed in the second well region, and
a second circuit area including circuitry configured to output the second output signal, the second circuit area including transistors formed in the first well region.

18. The integrated circuit of claim 17, further comprising a column of well taps disposed adjacent an edge of the standard cell box, the column of well taps configured to connect the first well region to a voltage supply in the first supply domain and to connect the second well region to a voltage supply in the second supply domain.

19. The integrated circuit of claim 17, wherein the means for translating the second input signal is substantially a copy of the means for translating the first input signal mirrored about an axis parallel to the rows of standard cells.

20. The integrated circuit of claim 17, wherein the means for translating the second input signal is substantially a copy of the means for translating the first input signal rotated about a midpoint of an edge of the means for translating the first input signal.

21. The integrated circuit of claim 17, wherein the rows of standard cell include metal-programmable standard cells.

22. The integrated circuit of claim 17, wherein the means for translating the first input signal is adjacent to the means for translating the second input signal.

23. The integrated circuit of claim 17, wherein the first row of the rows of standard cells as adjacent an edge of the standard cell box.

24. An integrated circuit, comprising:
a first standard cell box and a second standard cell box, each standard cell box comprising rows of standard cells, each of the rows of standard cells including a well region extending across the respective standard cell box;
a column of well taps disposed between the first and the second standard cell boxes;
a means for translating a first input signal in a first supply domain to a first output signal in a second supply domain,
the means for translating including
a first circuit area including circuitry configured to receive the first input signal, the first circuit area disposed in a portion of a first one of the rows of standard cells of the first standard cell box, the first circuit area including transistors formed in the well region of the first one of the rows of standard cells of the first standard cell box, and
a second circuit area including circuitry configured to output the first output signal, the second circuit area disposed in a portion of a first one of the rows of standard cells of the second standard cell box, the second circuit area including transistors formed in the well region of the first one of the rows of standard cells of the second standard cell box; and
a means for translating a second input signal in the second supply domain to a second output signal in the first supply domain,
the means for translating including
a first circuit area including circuitry configured to receive the second input signal, the first circuit area disposed in a portion of a second one of the rows of standard cells of the second standard cell box, the first circuit area including transistors formed in the well region of the second one of the rows of standard cells of the second standard cell box, and
a second circuit area including circuitry configured to output the second output signal, the second circuit area disposed in a portion of a second one of the rows of standard cells of the first standard cell box, the second circuit area including transistors formed in the well region of the second one of the rows of standard cells of the first standard cell box.

25. The integrated circuit of claim 24, wherein the first one of the rows of standard cells of the first standard cell box and the first one of the rows of standard cells of the second standard cell box are collinear, and the second one of the rows of standard cells of the first standard cell box and the second one of the rows of standard cells of the second standard cell box are collinear.

26. The integrated circuit of claim 24, wherein the first circuit area of the means for translating the first input signal is adjacent to the column of well taps, the second circuit area of the means for translating the first input signal is adjacent to the column of well taps, the first circuit area of the means for translating the second input signal is adjacent to the column of well taps, and the second circuit area of the means for translating the second input signal is adjacent to the column of well taps.

27. The integrated circuit of claim 26, wherein the first one of the rows of standard cells of the first standard cell box and the second one of the rows of standard cells of the first standard cell box are adjacent.

28. The integrated circuit of claim 24, wherein the column of well taps
provides a connection between the well region of the first one of the rows of standard cells of the first standard cell box and a voltage supply in the first supply domain,
provides a connection between the well region of the first one of the rows of standard cells of the second standard cell box and a voltage supply in the second supply domain,
provides a connection between the well region of the second one of the rows of standard cells of the first standard cell box and the voltage supply in the first supply domain, and
provides a connection between the well region of the second one of the rows of standard cells of the second standard cell box and the voltage supply in the second supply domain.

29. The integrated circuit of claim 28, wherein the well region of the first one of the rows of standard cells of the first standard cell box and the well region of the second one of the rows of standard cells of the first standard cell box are contiguous, and the well region of the first one of the rows of standard cells of the second standard cell box and the well region of the second one of the rows of standard cells of the second standard cell box are contiguous.

30. The integrated circuit of claim 24, wherein the means for translating the second input signal is substantially a rotated copy of the means for translating the first input signal.

31. The integrated circuit of claim 24, wherein the rows of standard cells include metal-programmable standard cells.

32. A circuit operation method, comprising:
providing a standard cell box comprising rows of standard cells, a first row and a second row of the rows of standard cells including a first well region extending across the standard cell box, a third row and a fourth row of the rows of standard cells including a second well region extending across the standard cell box;
translating a first input signal in a first supply domain to a first output signal in a second supply domain using a first voltage level shifter cell comprising:
a first circuit area including circuitry configured to receive the first input signal, the first circuit area including transistors formed in the first well region, and
a second circuit area including circuitry configured to output the first output signal, the second circuit area including transistors formed in the second well region; and
translating a second input signal in the second supply domain to a second output signal in the first supply domain using a second voltage level shifter cell comprising:
a first circuit area including circuitry configured to receive the second input signal, the first circuit area including transistors formed in the second well region, and
a second circuit area including circuitry configured to output the second output signal, the second circuit area including transistors formed in the first well region.

33. The method of claim 32, further comprising providing a column of well taps disposed adjacent an edge of the standard cell box, the column of well taps configured to connect the first well region to a voltage supply in the first supply domain and to connect the second well region to a voltage supply in the second supply domain.

34. The method of claim 32, wherein the second voltage level shifter cell is substantially a copy of the first voltage level shifter cell, the copy being mirrored about an axis parallel to the rows of standard cells or being rotated about a midpoint of an edge of the first voltage level shifter cell.

35. The method of claim 32, wherein the first voltage level shifter cell is adjacent to the second voltage level shifter cell.
